(19) United States
(12) Patent Application Publication
(10) Pub. No.: US 2026/0324174 A1
(43) Pub. Date: Oct. 15, 2026

(54) DISPLAY MODULE, METHOD FOR MANUFACTURING THE SAME, AND ELECTRONIC DEVICE INCLUDING THE DISPLAY MODULE

(71) Applicant: Samsung Display Co., LTD., Yongin-si (KR)

(72) Inventors: HYEMIN LEE, Yongin-si (KR); OHJUNE KWON, Yongin-si (KR); HYOJEONG KWON, Yongin-si (KR); WOO YONG SUNG, Yongin-si (KR); Soomin OH, Yongin-si (KR); KWANHYUCK YOON, Yongin-si (KR); JEONGSEOK LEE, Yongin-si (KR); SEUNGGUN CHAE, Yongin-si (KR); Sangyeon HWANG, Yongin-si (KR)

(21) Appl. No.: 19/550,965

(22) Filed: Feb. 26, 2026

(30) Foreign Application Priority Data
Apr. 11, 2025 (KR) 10-2025-0047377

(51) Int. Cl. H10H 29/855; H10H 20/01; H10H 29/01

(52) U.S. Cl. CPC H10H 29/8552; H10H 20/019; H10H 29/0363

(57) ABSTRACT

A display module includes a base substrate, a display layer disposed on the base substrate, where the display layer includes a light emitting element, an edge fluorine film disposed on an outer portion of a lower surface of the base substrate which faces an upper surface of the base substrate, and a light blocking layer including an edge light blocking portion, which overlaps the edge fluorine film, and an inner light blocking portion disposed on the lower surface of the base substrate not to overlap the edge fluorine film.

This application claims priority to Korean Patent Application No. 10-2025-0047377, filed on April 11, 2025, and all the benefits accruing therefrom under 35 U.S.C. §119, the content of which in its entirety is herein incorporated by reference.

### BACKGROUND

### 1 Field

Embodiments of the present disclosure described herein relate to a display module, a manufacturing method thereof, and an electronic device including the display module, and more particularly, relate to a display module including a lower light blocking layer, a method for manufacturing the display module, and an electronic device including the display module.

### 2 Description of the Related Art

Multimedia electronic devices, such as a television, a mobile phone, a tablet computer, a car navigation device, a game machine, and a wearable device, may include a display module that generates an image. The display module may improve image quality by reducing reflection of external light through a light blocking layer attached to a surface opposite to a light emitting surface and preventing an internal light sources from being undesirably exposed to the outside. The light blocking layer may reduce an interference phenomenon that is likely to occur inside a display device, thereby ensuring accurate color representation and clarity.

When a mother substrate includes glass, an etching solution including fluorine may be used to etch the mother substrate in the manufacturing process of the display device. Plasma processing may be performed to remove fluorine atoms remaining on an etched surface of the mother substrate.

### SUMMARY

Embodiments of the present disclosure provide a display module with improved light-blocking effect and strength and an electronic device including the same.

Embodiments of the present disclosure provide a method for manufacturing a display module with improved light-blocking effect and strength.

According to an embodiment, a display module includes a base substrate, a display layer disposed on the base substrate, where the display layer includes a light emitting element, an edge fluorine film disposed on an outer portion of a lower surface of the base substrate which faces an upper surface of the base substrate, and a light blocking layer including an edge light blocking portion, which overlaps the edge fluorine film, and an inner light blocking portion disposed on the lower surface of the base substrate not to overlap the edge fluorine film.

In an embodiment, the edge light blocking portion may include a first edge light blocking portion directly disposed on a lower surface of the edge fluorine film and a second edge light blocking portion directly disposed on a lower surface of the first edge light blocking portion.

In an embodiment, the second edge light blocking portion and the inner light blocking portion may be integrally formed with each other as a single unitary indivisible part.

In an embodiment, a lower surface of the light blocking layer may be a flat surface.

In an embodiment, the edge light blocking portion may have a smaller thickness than the inner light blocking portion.

In an embodiment, the base substrate may include glass.

In an embodiment, the light blocking layer may include a black coloring agent.

In an embodiment, the inner light blocking portion may have a rectangular shape on in a plan view, and the edge light blocking portion may be disposed to surround the inner light blocking portion such that the light blocking layer has a rectangular shape in the plan view.

In an embodiment, the edge light blocking portion may have a width greater than or equal to about 0.1 millimeter (mm) and less than about 2 mm in a plan view.

According to an embodiment, a method for manufacturing a display module includes forming a preliminary base substrate and a fluorine film on a lower surface of the preliminary base substrate by etching a lower surface of a mother substrate with a fluorine solution, forming a display layer including a light emitting element on an upper surface of the preliminary base substrate which faces the lower surface of the preliminary base substrate, forming a first edge light blocking portion on a portion of a lower surface of the fluorine film, processing the fluorine film with N₂ plasma from below the preliminary base substrate, forming a light blocking layer including the first edge light blocking portion, a second edge light blocking portion overlapping the first edge light blocking portion, and an inner light blocking portion not overlapping the first edge light blocking portion, by providing a black resin to a lower surface of the first edge light blocking portion and the lower surface of the preliminary base substrate exposed after the N₂ plasma processing, and forming a base substrate by removing a portion of the preliminary base substrate not overlapping the light blocking layer.

In an embodiment, in the forming the light blocking layer, an exposed lower surface of the second edge light blocking portion and an exposed lower surface of the inner light blocking portion may be formed to be on a same plane.

In an embodiment, the mother substrate may include glass.

In an embodiment, each of the forming the first edge light blocking portion and the forming the light blocking layer may include printing the black resin.

In an embodiment, in the forming the light blocking layer, the inner light blocking portion may have a rectangular shape in a plan view, and the first edge light blocking portion and the second edge light blocking portion may respectively be formed to surround the inner light blocking portion such that the light blocking layer has a rectangular shape in the plan view.

In an embodiment, in the forming the first edge light blocking portion, the first edge light blocking portion may have a width greater than or equal to about 0.1 mm and less than about 2 mm in a plan view.

According to an embodiment, an electronic device includes a display module which generates an image. In such an embodiment, the display module includes a base substrate, a display layer disposed on the base substrate, where the display layer includes a light emitting element, an edge fluorine film disposed on an outer portion of a lower surface of the base substrate which faces an upper surface of the base substrate, and a light blocking layer including an edge light blocking portion, which overlaps the edge fluorine film, and an inner light blocking portion disposed on the lower surface of the base substrate not to overlap the edge fluorine film.

In an embodiment, the edge light blocking portion may include a first edge light blocking portion directly disposed on a lower surface of the edge fluorine film and a second edge light blocking portion directly disposed on a lower surface of the first edge light blocking portion.

In an embodiment, the second edge light blocking portion and the inner light blocking portion may be integrally formed with each other as a single unitary indivisible part.

In an embodiment, the electronic device may further include at least one selected from a processor, a memory, and a power module.

In an embodiment, the electronic device may be a television, a monitor, a billboard, a personal computer, a laptop computer, a personal digital assistant, a device for a vehicle, a game machine, a smart phone, a tablet computer, a smart watch, or a camera.

### BRIEF DESCRIPTION OF THE DRAWINGS

The above and other features of embodiments of the present disclosure will become apparent by describing in detail embodiments thereof with reference to the accompanying drawings, in which:

FIG. 1A is a block diagram of an electronic device according to an embodiment;

FIG. 1B illustrates schematic views of electronic devices according to various embodiments;

FIG. 2 is a perspective view of an electronic device according to an embodiment;

FIG. 3 is a perspective view of a display module according to an embodiment;

FIG. 4 is a sectional view of the display module according to an embodiment;

FIG. 5 is a sectional view of a portion of the display module according to an embodiment;

FIG. 6 is a plan view of the display module according to an embodiment;

FIG. 7 is a perspective view of a light blocking layer according to an embodiment;

FIG. 8 is a sectional view of the light blocking layer according to an embodiment;

FIG. 9 is a flowchart illustrating a display module manufacturing method according to an embodiment; and

FIGS. 10 to 13 are sectional views illustrating processes of the display module manufacturing method according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In this specification, when a component (or, an area, a layer, a part, etc.) is referred to as being “ “connected to” or “coupled to” another component, this means that the component may be directly connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The expression “directly disposed” used herein may mean that there is no additional layer, film, area, or plate between one portion, such as a layer, a film, an area, or a plate, and another portion. For example, the expression “directly disposed” may mean that two layers or two members are disposed without an additional member such as an adhesive member therebetween.

The expression “areas/portions correspond to each other” used herein may mean “overlap each other” and is not limited to having the same area and/or the same shape. In addition, the expression “areas/portions overlap each other” used herein includes a case in which the areas/portions indicated as overlapping each other when viewed from above a plane at least partially overlap each other when viewed from above the plane.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of a display module, a display module manufacturing method, and an electronic device will be described with reference to the accompanying drawings.

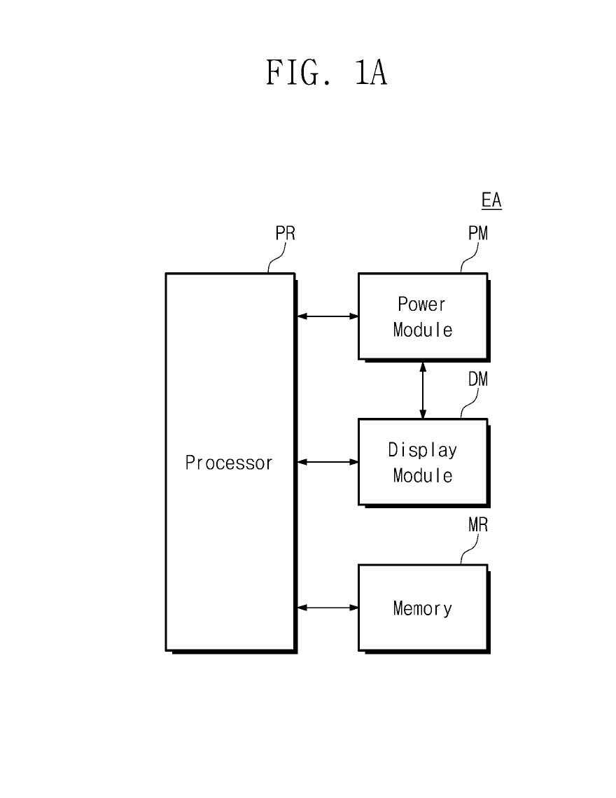

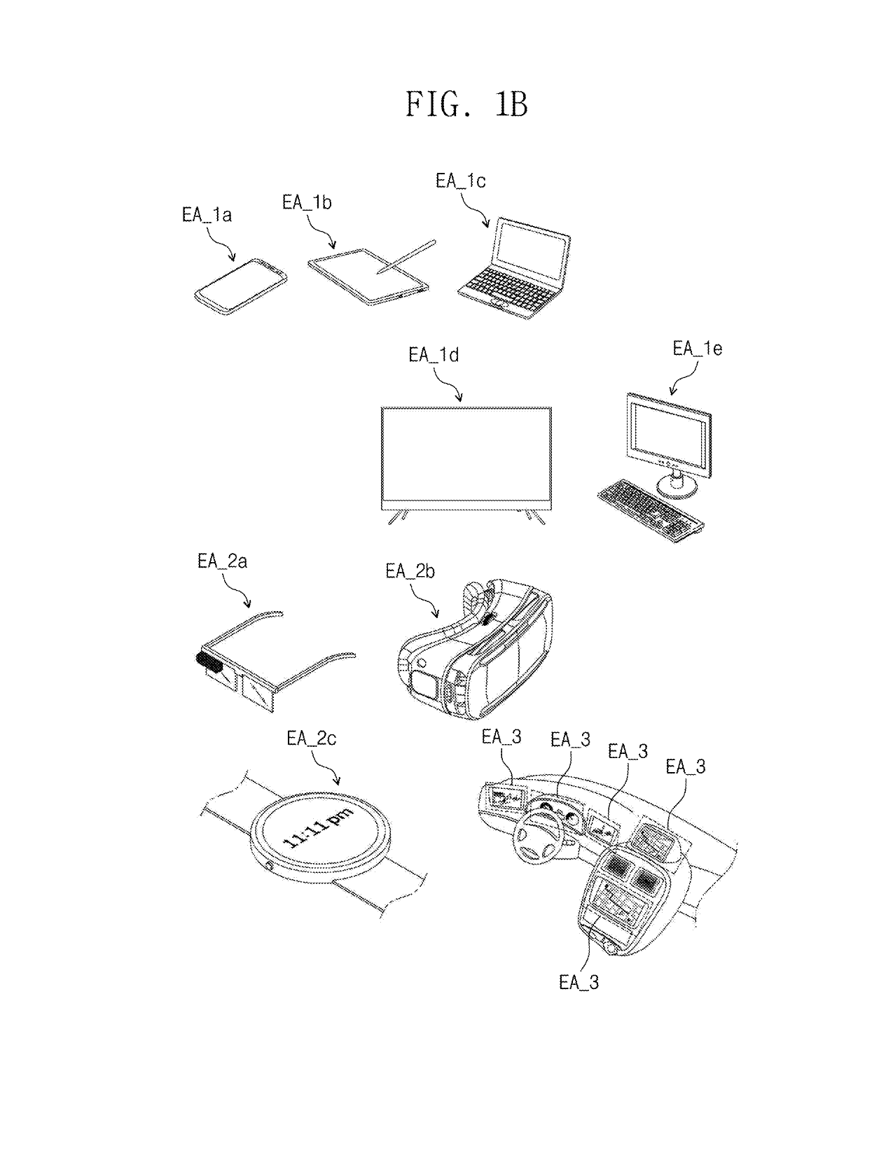

FIG. 1A is a block diagram of an electronic device according to an embodiment. Referring to FIG. 1A, the electronic device EA according to an embodiment may include a display module DM, a processor PR, a memory MR, and a power module PM.

The processor PR may include at least one selected from a central processing unit (CPU), an application processor (AP), a graphic processing unit (GPU), a communication processor (CP), an image signal processor (ISP), and a controller.

Data information used for operation of the processor PR or the display module DM may be stored in the memory MR. When the processor PR executes an application stored in the memory MR, an image data signal and/or an input control signal may be transferred to the display module DM, and the display module DM may process the provided signal and may output image information through a display screen.

The power module PM may include a power supply module such as a power adapter or a battery device and a power conversion module that converts power supplied by the power supply module and generates power used for operation of the electronic device EA.

At least one of the components of the electronic device EA described above may be included in a display device according to an embodiment. In addition, some of the separate modules functionally included in one module may be included in the display device, and the others may be provided separately from the display device. In an embodiment, for example, the display device may include an embodiment of the display module DM to be described below. The processor PR, the memory MR, and the power module PM may be provided in the form of other devices in the electronic device EA rather than the display device.

FIG. 1B illustrates schematic views of electronic devices according to various embodiments.

Referring to FIG. 1B, various electronic devices to which a display device according to an embodiment is applied may include not only electronic devices for displaying images, such as a smart phone EA_1a, a tablet personal computer (PC) EA_1b, a laptop computer EA_1c, a television (TV) EA_1d, and a desk monitor EA_1e, but also wearable electronic devices including a display module, such as smart glasses EA_2a, a head mounted display EA_2b, and a smart watch EA_2c, and vehicle electronic devices 10_3 including a display module, such as center information displays (CID) disposed on an instrument panel, a center fascia, and a dashboard of a vehicle and a room mirror display.

A display device according to an embodiment may be applied to various electronic devices. An electronic device according to an embodiment may further include modules or devices having other additional functions, in addition to the display device.

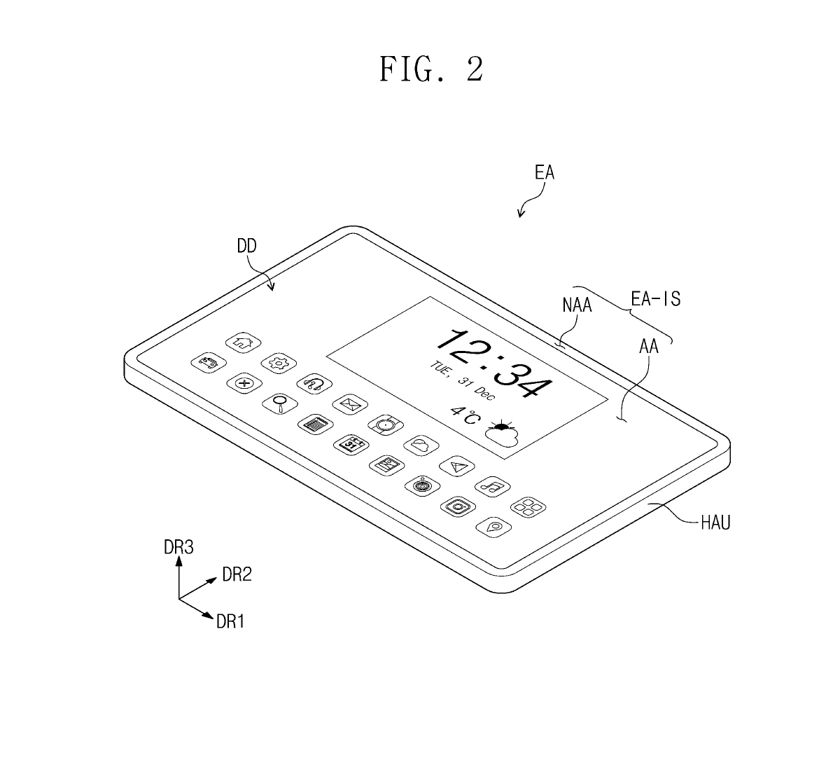

FIG. 2 is a perspective view illustrating an electronic device according to an embodiment.

An embodiment of the electronic device EA may include a display device DD that displays an image through a display surface EA-IS. The display device DD may be disposed or accommodated in a housing HAU. The electronic device EA may include the display device DD and a controller that controls operation of the display device DD.

The display surface EA-IS of the electronic device EA, when viewed from above a plane (or when viewed in a plan view), may have a rectangular shape with long sides extending in a first direction DR1 and short sides extending in a second direction DR2 crossing the first direction DR1. However, without being limited thereto, the display surface EA-IS may have various shapes such as a circular shape and a polygonal shape.

In this specification, a third direction DR3 may be defined as a direction substantially perpendicular to a plane defined by the first direction DR1 and the second direction DR2. Front surfaces (or, upper surfaces) and rear surfaces (or, lower surfaces) of members constituting the electronic device EA may be opposite each other in the third direction DR3, and the normal directions of the front surfaces and the rear surfaces may be substantially parallel to the third direction DR3. The third direction DR3 may be a thickness direction of the electronic device EA. The separation distances between the front surfaces and the rear surfaces that are defined in the third direction DR3 may correspond to the thicknesses of the members.

The expression “when viewed from above a plane” or “in a plan view” used herein may mean that it is viewed in the third direction DR3. That is, the expression “when viewed from above a plane” or “in a plan view” may be described based on the plane defined by the first direction DR1 and the second direction DR2. The expression “on a cross-section” used herein may mean that it is viewed in the first direction DR1 or the second direction DR2. The directions indicated by the first to third directions DR1, DR2, and DR2 may be relative concepts and may be changed to other directions.

In FIG. 2, an embodiment where the electronic device EA is a tablet terminal is illustrated as an example. Electronic modules, a camera module, and a power module mounted on the main board, together with the display device DD, may be disposed in the bracket/housing HAU to constitute the tablet terminal. Embodiments are not limited thereto, and the display device DD and the display module according to an embodiment to be described below may be applied to small and medium-sized electronic devices, such as a personal computer, a laptop computer, a personal digital assistant, a car navigation unit, a game machine, a smart phone, a tablet computer, a smart watch, and a camera, as well as large electronic devices such as a television, a monitor, and a billboard. However, these are merely illustrative, and the display device DD according to an embodiment may be employed as other electronic devices without departing from the spirit and scope of the present disclosure. The electronic device EA including the display device DD may be referred to as a display device.

In an embodiment, the electronic device EA including the display device DD having a flat display surface is illustrated, but the present disclosure is not limited thereto. The electronic device EA may include a curved display surface or a three-dimensional display surface. For example, the three-dimensional display surface may include a plurality of display areas indicating different directions and may include a bent display surface. The electronic device EA according to an embodiment may be a flexible electronic device. The flexible electronic device may be a foldable electronic device capable of being folded.

In an embodiment, as illustrated in FIG. 2, the display surface EA-IS includes an active area AA where an image is displayed and a bezel area NAA adjacent to the active area AA. The bezel area NAA is an area where an image is not displayed. In FIG. 2, icon images are illustrated as an example of an image. The active area AA may be referred to as a display area of the display device DD, and the bezel area NAA may be referred to as a non-display area of the display device DD.

In an embodiment, as illustrated in FIG. 2, the active area AA may have a substantially quadrangular shape. The "substantially quadrangular shape" includes not only a quadrangular shape in the mathematical sense, but also a quadrangular shape in which the boundaries of curves rather than vertexes are defined in the vertex areas (or the corner areas).

The bezel area NAA may surround the active area AA. However, without being limited thereto, the shape of the bezel area NAA may be modified. In an embodiment, for example, the bezel area NAA may be disposed on only one side of the active area AA.

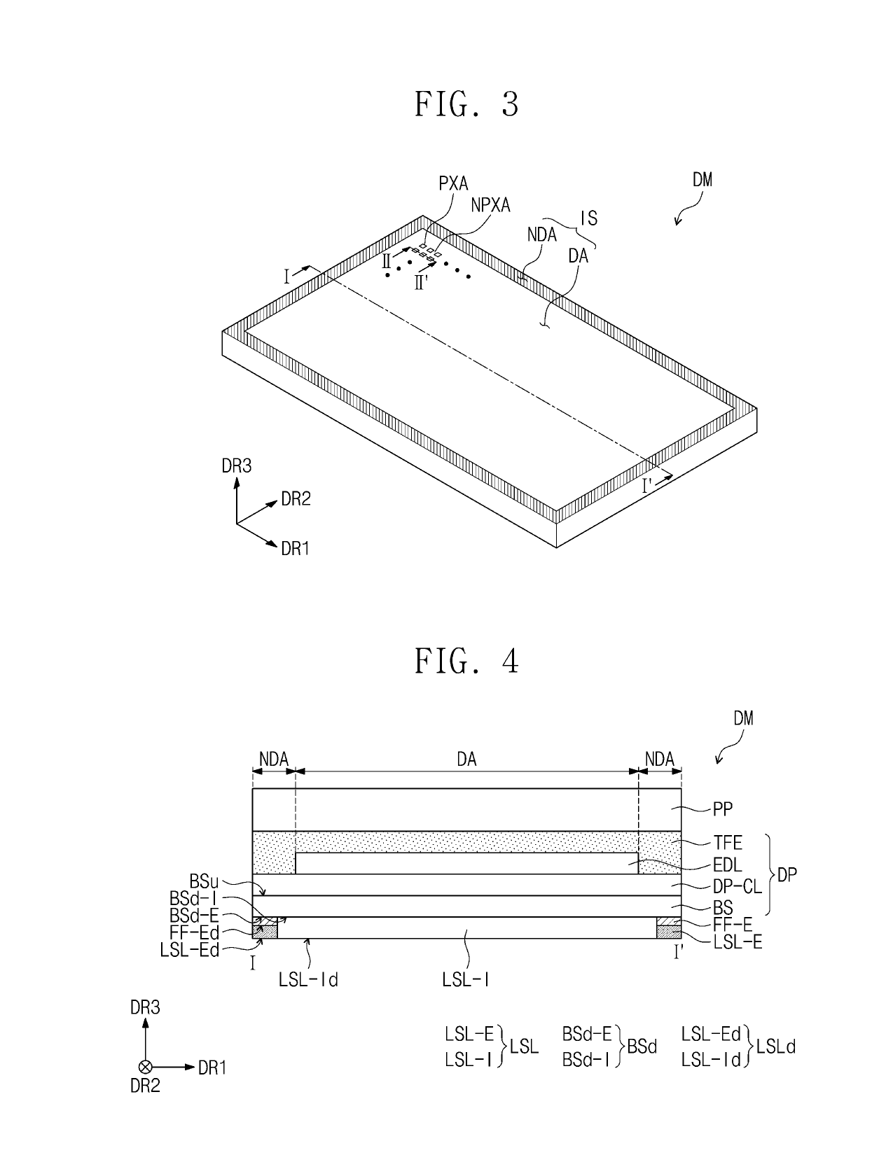

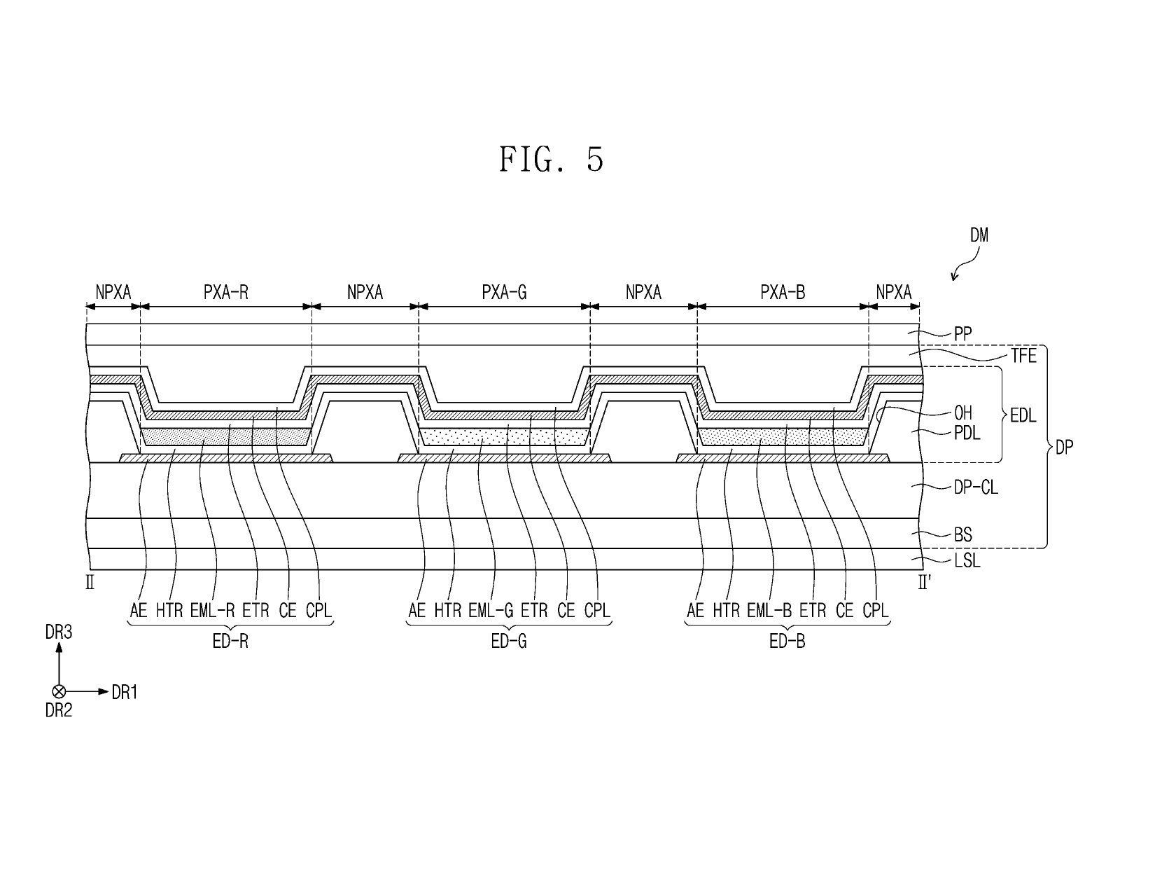

FIG. 3 is a perspective view of the display module according to an embodiment of the present disclosure. FIG. 4 is a sectional view of the display module according to an embodiment. FIG. 5 is a detailed sectional view illustrating a portion of the display module according to an embodiment. FIG. 4 is a sectional view corresponding to line I-I’ of FIG. 3, and FIG. 5 is a sectional view corresponding to line II-II’ of FIG. 3. The display module DM according to an embodiment described with reference to FIG. 3 may be included in the display device DD illustrated in FIG. 2.

Referring to FIG. 3, an embodiment of the display module DM may include a display surface IS. The display module DM may display an image through the display surface IS. The display surface IS of the display module DM may correspond to the display surface EA-IS of the electronic device EA.

The display surface IS may include a display area DA and a non-display area NDA. A plurality of pixel areas PXA may be disposed in the display area DA. A peripheral area NPXA is disposed around the pixel areas PXA in a plan view. The pixel areas PXA may be referred to as light emitting areas, and the peripheral area NPXA may be referred to as a non-light emitting area.

The display module DM according to an embodiment may include the plurality of pixel areas PXA repeatedly disposed in the entire display area DA. The pixel areas PXA in the display module DM according to an embodiment may be arranged in a stripe form when viewed from above the plane. Referring to FIG. 3, in an embodiment, the plurality of pixel areas PXA may be aligned along the first directional axis DR1 or the second directional axis DR2. However, embodiments are not limited thereto, and the pixel areas PXA may be arranged in a PENTILE^{TM} form or a Diamond Pixel^{TM} form.

In an embodiment, the pixel areas PXA may have similar planar areas as each other as shown in FIG. 3, but embodiments are not limited thereto, and the pixel areas PXA may have different planar areas depending on the wavelength range of emitted light.

The pixel areas PXA may not be disposed in the non-display area NDA of the display surface IS, and the non-display area NDA may surround the display area DA. However, without being limited thereto, in an embodiment of the present disclosure, the non-display area NDA may be omitted or may be disposed on only one side of the display area DA.

Referring to FIGS. 4 and 5, the display module DM according to an embodiment includes a base substrate BS, a display layer EDL, an edge fluorine film FF-E, and a light blocking layer LSL.

Referring to FIGS. 4 and 5, the display module DM according to an embodiment may include a display panel DP. The base substrate BS and the display layer EDL may be components of the display panel DP. The display panel DP may be a component that substantially generates image data. An embodiment of the display panel DP may be a component that is included in an embodiment of the electronic device EA (refer to FIG. 2) and that displays an image. An embodiment of the display panel DP may be an emissive display panel. In an embodiment, the display panel DP may include an inorganic light emitting material such as a quantum dot.

The display panel DP may include the base substrate BS, a circuit layer DP-CL, the display layer EDL, and an encapsulation layer TFE sequentially stacked in the direction of the third directional axis DR3. That is, the display layer EDL may be disposed on the base substrate BS.

The display layer EDL may include light emitting elements ED-R, ED-G, and ED-B. A plurality of pixel areas PXA-R, PXA-G, and PXA-B may be areas where light generated by the light emitting elements ED-R, ED-G, and ED-B is emitted.

In an embodiment, the encapsulation layer TFE may be directly disposed on the display layer EDL. The encapsulation layer TFE may cover the light emitting elements ED-R, ED-G, and ED-B of the display layer EDL.

Referring to FIGS. 3 and 5, the pixel areas PXA may include the first to third pixel areas PXA-R, PXA-G, and PXA-B. In the display module DM according to an embodiment, the first to third pixel areas PXA-R, PXA-G, and PXA-B may be distinguished from one another when viewed from above the plane and may emit light in different wavelength ranges.

In addition, the display module DM according to an embodiment may include the peripheral area NPXA disposed around the first to third pixel areas PXA-R, PXA-G, and PXA-B. The peripheral area NPXA may set or define the boundaries between the first to third pixel areas PXA-R, PXA-G, and PXA-B. The peripheral area NPXA may surround each of the first to third pixel areas PXA-R, PXA-G, and PXA-B. In the peripheral area NPXA, a structure for preventing color mixing between the first to third pixel areas PXA-R, PXA-G, and PXA-B, for example, a pixel defining layer PDL may be disposed to overlap the peripheral area NPXA.

The first to third pixel areas PXA-R, PXA-G, and PXA-B may be areas distinguished from one another by the pixel defining layer PDL. The peripheral area NPXA may be an area between the first to third pixel areas PXA-R, PXA-G, and PXA-B adjacent to one another and may be an area corresponding to the pixel defining layer PDL.

The first to third pixel areas PXA-R, PXA-G, and PXA-B may be areas where light generated by the first to third light emitting elements ED-R, ED-G, and ED-B is emitted. The first to third pixel areas PXA-R, PXA-G, and PXA-B may be spaced apart from one another when viewed from above the plane.

The pixel defining layer PDL may distinguish or partition the first to third light emitting elements ED-R, ED-G, and ED-B from one another. Light emitting layers EML-R, EML-G, and EML-B of the first to third light emitting elements ED-R, ED-G, and ED-B may be disposed in pixel openings OH defined in the pixel defining layer PDL to be distinguished from one another.

The pixel defining layer PDL may include or be formed of a polymer resin. In an embodiment, for example, the pixel defining layer PDL may include or be formed of a polyacrylate resin or a polyimide resin. In addition, the pixel defining layer PDL may further include an inorganic material in addition to the polymer resin. The pixel defining layer PDL may include a light absorbing material or may include a black pigment or a black dye. The pixel defining layer PDL including the black pigment or the black dye may implement a black pixel defining layer.

The first to third pixel areas PXA-R, PXA-G, and PXA-B may be distinguished from one another depending on the colors of light generated by the first to third light emitting elements ED-R, ED-G, and ED-B. For example, in the display module DM according to an embodiment, the first pixel area PXA-R may correspond to a red light emitting area, the second pixel area PXA-G may correspond to a green light emitting area, and the third pixel area PXA-B may correspond to a blue light emitting area.

In the display module DM according to an embodiment, the light emitting elements ED-R, ED-G, and ED-B may emit light in different wavelength ranges. For example, in an embodiment, the first light emitting element ED-R may correspond to a red light emitting element that emits red light, the second light emitting element ED-G may correspond to a green light emitting element that emits green light, and the third light emitting element ED-B may correspond to a blue light emitting element that emits blue light.

Although three pixel areas PXA-R, PXA-G, and PXA-B distinguished from one another are illustrated in FIG. 5, embodiments are not limited thereto, and the display module DM according to an embodiment may include four or more light emitting areas having different emission characteristics from each other.

In the display panel DP, the base substrate BS may be a member that provides a base surface on which the edge fluorine film FF-E, the light blocking layer LSL, the display layer EDL, and the circuit layer DP-CL are disposed. The base substrate BS may be a glass substrate, a metal substrate, or a plastic substrate. However, embodiments are not limited thereto, and the base substrate BS may be an inorganic layer, an organic layer, or a composite layer.

The base substrate BS may include glass. In an embodiment, the display module DM may include the base substrate BS including glass and the light blocking layer LSL to be described below and may exhibit strong durability. In an embodiment of a manufacturing process of the base substrate BS including glass, an etching solution including fluorine may be used to etch a mother substrate. The edge fluorine film FF-E may be formed by the etching solution including fluorine. The edge fluorine film FF-E may be formed on an outer portion BSd-E of a lower surface BSd of the base substrate BS. Detailed description of the edge fluorine film FF-E will be given below.

In an embodiment, the base substrate BS may have a thickness greater than or equal to about 0.1 millimeter (mm) and less than about 0.3 mm. In an embodiment, for example, the base substrate BS may have a thickness of about 0.2 mm. In an embodiment, even though the display module DM includes the thin base substrate BS having a thickness greater than or equal to about 0.1 mm and less than about 0.3 mm, the display module DM may include the edge fluorine film FF-E and the light blocking layer LSL disposed on one surface of the base substrate and may exhibit improved strength characteristics.

In an embodiment, the circuit layer DP-CL may be disposed on the base substrate BS. The circuit layer DP-CL may include a plurality of transistors (not illustrated). Each of the transistors (not illustrated) may include a control electrode, an input electrode, and an output electrode. In an embodiment, for example, the circuit layer DP-CL may include a switching transistor and a driving transistor for driving the light emitting elements ED-R, ED-G, and ED-B of the display layer EDL.

The encapsulation layer TFE may cover the light emitting elements ED-R, ED-G, and ED-B. The encapsulation layer TFE may seal the display layer EDL. The encapsulation layer TFE may be a thin film encapsulation layer. The encapsulation layer TFE may include a plurality of layers stacked one above another. The encapsulation layer TFE according to an embodiment may include at least one inorganic film and at least one organic film.

The display module DM according to an embodiment may further include an optical member PP. The optical member PP may be a reflection reducing layer that reduces reflectance due to external light. In an embodiment, for example, the optical member PP may include a polarizing film including a phase retarder and/or a polarizer, a plurality of reflective layers that allow reflected light beams to destructively interfere with each other, or color filters disposed corresponding to the pixel arrangement and emission color of the display panel DP. In an embodiment, the optical member PP may be omitted.

In an embodiment of the display module DM, each of the first to third light emitting elements ED-R, ED-G, and ED-B may include a first electrode AE, a hole transport area HTR, the light emitting layer EML-R, EML-G, or EML-B, an electron transport area ETR, and a second electrode CE. In addition, each of the light emitting elements ED-R, ED-G, and ED-B may further include a capping layer CPL disposed on the second electrode CE.

The first electrode AE may be exposed through the pixel opening OH of the pixel defining layer PDL.

The second electrode CE may be disposed over the first electrode AE. The second electrode CE may be disposed to face the first electrode AE with the light emitting layer EML-R, EML-G, or EML-B therebetween. The second electrode CE may be a cathode or an anode. In an embodiment, when the first electrode AE is an anode, the second electrode CE may be a cathode, and when the first electrode AE is a cathode, the second electrode CE may be an anode. The second electrode CE may be a common electrode. The second electrode CE may be a transmissive electrode, a transflective electrode, or a reflective electrode.

The first electrode AE may be separately disposed to correspond to each of the pixel areas PXA-R, PXA-G, and PXA-B. The second electrode CE may be provided as a common layer in all of the pixel areas PXA-R, PXA-G, and PXA-B.

The hole transport area HTR may be disposed between the first electrode AE and the light emitting layer EML-R, EML-G, or EML-B, and the electron transport area ETR may be disposed between the light emitting layer EML-R, EML-G, or EML-B and the second electrode CE. Referring to FIG. 5, the hole transport area HTR and the electron transport area ETR may each be provided as a common layer in all of the pixel areas PXA-R, PXA-G, and PXA-B. However, embodiments are not limited thereto, and the hole transport area HTR and the electron transport area ETR may be disposed to independently correspond to each of the pixel areas PXA-R, PXA-G, and PXA-B.

In an embodiment, each of the first to third light emitting elements ED-R, ED-G, and ED-B may further include the capping layer CPL. The capping layer CPL may be disposed on the second electrode CE. The capping layer CPL may include (or be defined by) a plurality of layers or a single layer. Referring to FIG. 5, in an embodiment of the display module DM, the capping layer CPL may be provided as a common layer in all of the pixel areas PXA-R, PXA-G, and PXA-B.

Referring to FIGS. 4 and 5, in an embodiment of the display module DM, the edge fluorine film FF-E is disposed on the outer portion BSd-E of the lower surface BSd of the base substrate BS that faces an upper surface BSu of the base substrate BS. In such an embodiment, on the lower surface BSd of the base substrate BS, the edge fluorine film FF-E may be disposed adjacent to the edge portion including the periphery to surround an empty area inside. In this specification, the fluorine film means a film including fluorine atoms. The edge fluorine film FF-F may be formed by forming a film including a fluorine compound, such as Si-F or AlF₃, on the surface of a glass substrate when the mother substrate is etched using a fluorine (F)-based etching solution, such as HF, CF₄, or SF₆, in a manufacturing process of the display module DM. However, a manufacturing method of the edge fluorine film FF-E is not limited thereto.

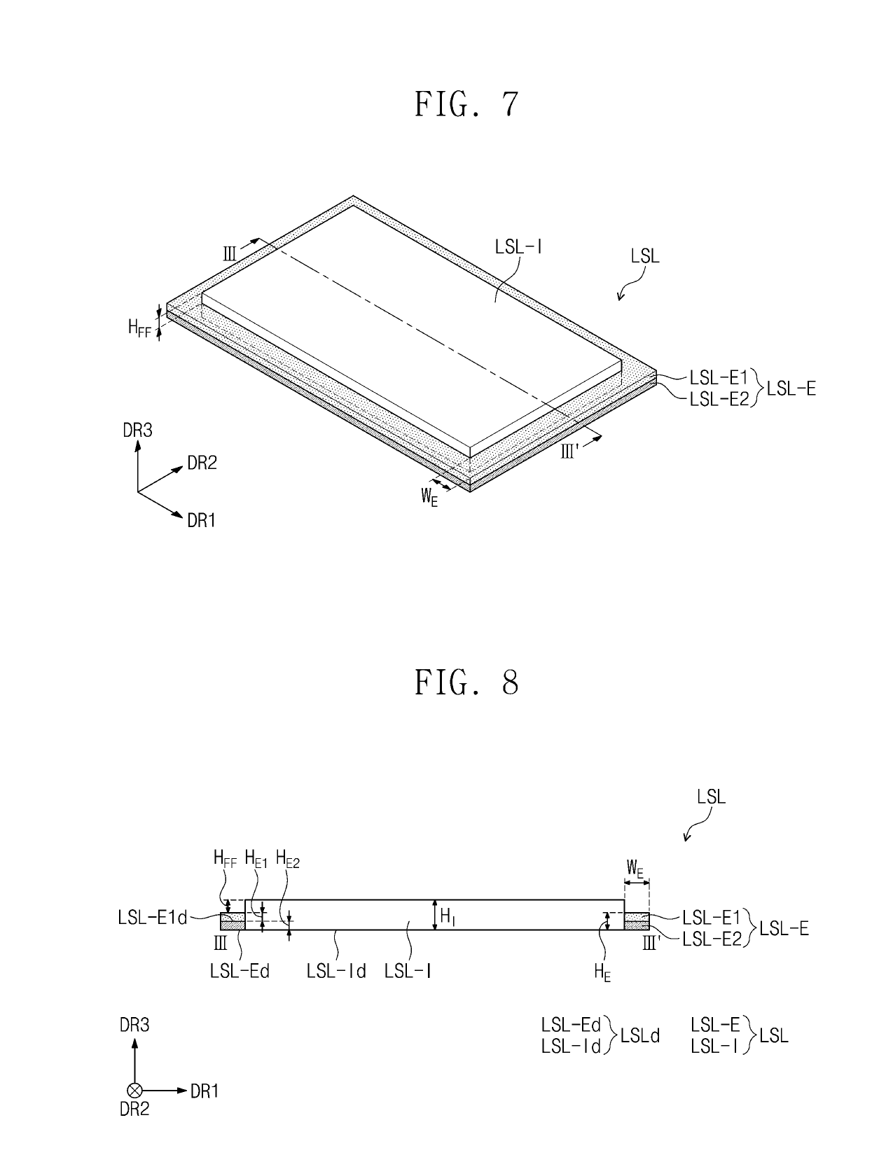

In an embodiment of the display module DM, the light blocking layer LSL includes an edge light blocking portion LSL-E and an inner light blocking portion LSL-I. The edge light blocking portion LSL-E is disposed under the edge fluorine film FF-E to overlap the edge fluorine film FF-E. The inner light blocking portion LSL-I is disposed on the lower surface BSd of the base substrate BS so as not to overlap the edge fluorine film FF-E. That is, the inner light blocking portion LSL-I may be disposed on an inner portion BSd-I of the lower surface BSd of the base substrate BS. That is, the edge light blocking portion SLS-E may have a shape surrounding a portion of a side surface of the inner light blocking portion LSL-I (refer to FIG. 7).

The light blocking layer LSL may be a layer that blocks external light and effectively prevents leakage of internal light. In addition, the light blocking layer LSL may be a layer that alleviates impact occurring under the display module DM to prevent a damage to the display panel DP. The light blocking layer LSL may completely overlap the lower surface of the base substrate.

The light blocking layer LSL may include a black coloring agent. The light blocking layer LSL may further include a base resin, and the black coloring agent may be mixed in the base resin. The light blocking layer LSL may be formed by curing the black resin including the base resin and the black coloring agent. The black coloring agent may include a black pigment or a black dye and may exhibit a black color. Since the light blocking layer LSL including the black coloring agent is entirely provided on the lower surface of the base substrate on the lower side of the display module DM, the display module DM may have high light blocking characteristics and may have high durability for impact occurring below.

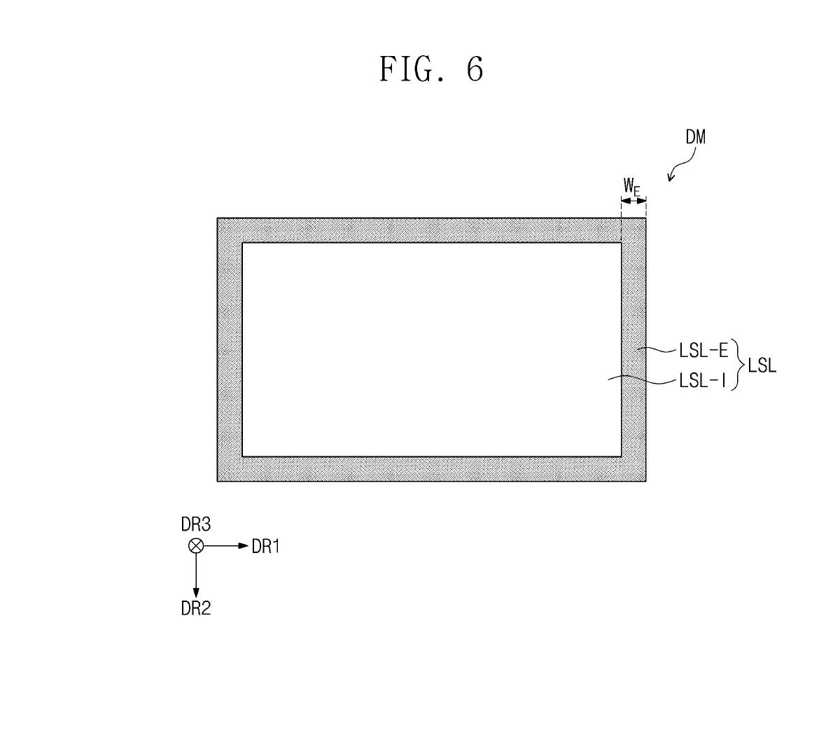

FIG. 6 is a plan view of the display module as viewed from below according to an embodiment. FIG. 7 is a perspective view of the light blocking layer according to an embodiment. FIG. 8 is a sectional view of the light blocking layer according to an embodiment. FIG. 8 is a sectional view corresponding to line III-III’ of FIG. 7. The light blocking layer LSL according to an embodiment is included in the display module DM according to the embodiment illustrated in FIG. 6. FIG. 8 is a detailed view of the light blocking layer LSL illustrated in FIG. 4.

Referring to FIGS. 4, 7 and 8, in the light blocking layer LSL according to an embodiment, the edge light blocking portion LSL-E may include a first edge light blocking portion LSL-E1 directly disposed on (i.e., disposed directly on) a lower surface FF-Ed of the edge fluorine film FF-E and a second edge light blocking portion LSL-E2 directly disposed on a lower surface LSL-E1d of the first edge light blocking portion LSL-E1. The first edge light blocking portion LSL-E1 and the second edge light blocking portion LSL-E2 may include a same material as or different materials from each other. In an embodiment, for example, the first edge light blocking portion LSL-E1 and the second edge light blocking portion LSL-E2 may include a black coloring agent, and the types or contents of the black coloring agents included in the first edge light blocking portion LSL-E1 and the second edge light blocking portion LSL-E2 may be different from each other. The first edge light blocking portion LSL-E1 and the second edge light blocking portion LSL-E2 may be distinguished from each other depending on the chronological order in which the first edge light blocking portion LSL-E1 and the second edge light blocking portion LSL-E2 are formed in a manufacturing process. However, irrespective of the manufacturing order in the manufacturing process, the portion directly disposed on the edge fluorine film FF-E may be referred to as the first edge light blocking portion LSL-E1, and the portion spaced apart from the edge fluorine film FF-E with the first edge light blocking portion LSL-E1 therebetween may be referred to as the second edge light blocking portion LSL-E2.

In an embodiment, the second edge light blocking portion LSL-E2 and the inner light blocking portion LSL-I may be integrally formed with each other as a single unitary indivisible part. That is, the second edge light blocking portion LSL-E2 and the inner light blocking portion LSL-I may be provided as a single structure without a separate coupling process. The second edge light blocking portion LSL-E2 and the inner light blocking portion LSL-I may be formed in a same process. In an embodiment where the second edge light blocking portion LSL-E2 and the inner light blocking portion LSL-I are integrally formed with each other as a single unitary indivisible part, the display module DM may exhibit increased durability characteristics because the second edge light blocking portion LSL-E2 and the inner light blocking portion LSL-I are provided as a single structure.

Referring to FIGS. 4 and 6, the inner light blocking portion LSL-I may have a rectangular shape on a plane parallel to the lower surface BSd of the base substrate BS. In addition, the edge light blocking portion LSL-E may be disposed to surround the inner light blocking portion LSL-I such that the light blocking layer LSL has a rectangular shape on the plane. The planar shapes of the inner light blocking portion LSL-I and the light blocking layer LSL may correspond to the shape of the display area DA of the display module DM and the shape of the display module DM. In another embodiment, the shape of the light blocking layer LSL, the shape of the inner light blocking portion LSL-I, and the shape of the display area DA may be various shapes on the plane parallel to the lower surface BSd of the base substrate BS without being limited to those illustrated in FIG. 6.

Referring to FIG. 8, on a plane defined by the first direction DR1 and the third direction DR3 (e.g., in a side view or when viewed in the second direction DR2), the edge light blocking portion LSL-E, the first edge light blocking portion LSL-E1, the second edge light blocking portion LSL-E2, and the inner light blocking portions LSL-I may each have a substantially rectangular shape. In such an embodiment where each of the first edge light blocking portion LSL-E1 and the second edge light blocking portion LSL-E2 has a substantially rectangular shape, the edge light blocking portion LSL-E may also have a substantially rectangular shape. The "substantially rectangular shape" includes not only a rectangular shape in the mathematical sense, but also a rectangular shape in which the boundaries of curves rather than vertexes are defined in the vertex areas (or, the corner areas).

Referring to FIG. 8, the thickness H_{E} of the edge light blocking portion LSL-E may be smaller than the thickness H_{I} of the inner light blocking portion LSL-I. The thickness H_{E} of the edge light blocking portion LSL-E may be equal to the sum of the thickness H_{E1} of the first edge light blocking portion LSL-E1 and the thickness H_{E2} of the second edge light blocking portion LSL-E2. The sum of the thickness H_{E} of the edge light blocking portion LSL-E and the thickness H_{FF} of the edge fluorine film FF-E may be equal to the thickness H_{I} of the inner light blocking portion LSL-I, and therefore the thickness H_{E} of the edge light blocking portion LSL-E may be smaller than the thickness H_{I} of the inner light blocking portion LSL-I. Accordingly, a step (or a stepped structure) may be generated or defined between the edge light blocking portion LSL-E and the inner light blocking portion LSL-I. The step may be a step having a length (or a vertical height difference) equal to the thickness H_{FF} of the edge fluorine film FF-E.

Referring to FIGS. 4 and 8, a lower surface LSLd of the light blocking layer LSL may be a flat surface. The lower surface LSLd of the light blocking layer LSL may include a lower surface LSL-Ed of the edge light blocking portion LSL-E and a lower surface LSL-Id of the inner light blocking portion LSL-I. That is, the lower surface LSL-Ed of the edge light blocking portion LSL-E and the lower surface LSL-Id of the inner light blocking portion LSL-I may be on a same plane or coplanar (i.e., collectively defining a same planar surface). The lower surface LSL-Ed of the edge light blocking portion LSL-E may be referred to as being the same as the lower surface of the second edge light blocking portion LSL-E2. In a case where the lower surface of the light blocking layer LSL is a flat surface, edge control may be facilitated due to the structure of the edge fluorine film FF-E and the first edge light blocking portion LSL-E1 in the display module DM when the second edge light blocking portion LSL-E2 and the inner light blocking portion LSL-I are formed. The "edge control" may mean controlling the application of an ink (e.g., a black resin) having a specific viscosity, which is the material of the light blocking layer LSL before curing, to a target area in a process of forming the light blocking layer. When the structure of the edge fluorine film FF-E and the first edge light blocking portion LSL-E1 does not exist, the edge control may not be easy, and therefore the thickness of the light blocking layer LSL may be decreased from the inside of the light blocking layer LSL toward the edge. When the edge control is not easy, the thickness of the light blocking layer may not be uniform so that a light leakage phenomenon may partially occur or a light blocking effect may not be uniform. Accordingly, the display quality of the display module DM may be deteriorated. In an embodiment, the lower surface LSLd of the light blocking layer LSL is a flat surface, such that the display module DM may exhibit high display quality because the light leakage phenomenon is improved.

The lower surface LSLd of the light blocking layer LSL may be a substantially flat surface. The "substantially flat surface" includes not only a flat surface in the mathematical sense, but also an overall uniform surface. Due to the structure of the edge fluorine film FF-E and the first edge light blocking portion LSL-E1, the occurrence of a slope at the edge of the light blocking layer LSL may be improved. That is, the slope at the edge of the light blocking layer LSL may be shortened so that the lower surface LSLd of the light blocking layer LSL may have a shape close to a flat surface. When the lower surface LSLd of the light blocking layer LSL is a substantially flat surface, the display module DM may exhibit high display quality because the light leakage phenomenon is improved.

Referring back to FIG. 4, in an embodiment of the display module DM, the inner light blocking portion LSL-I may be disposed to overlap the display area DA. That is, in an embodiment of the display module DM, on the plane parallel to the lower surface BSd of the base substrate BS, the area corresponding to the inner light blocking portion LSL-I may include the display area DA. Since the thickness H_{E} of the edge light blocking portion LSL-E and the thickness H_{I} of the inner light blocking portion LSL-I are different from each other, the display quality of the display module DM may not be uniform in a case where both the inner light blocking portion LSL-I and the edge light blocking portion LSL-E are disposed to overlap the display area DA. In an embodiment, only the inner light blocking portion LSL-I is disposed to overlap the display area DA in an embodiment of the display module DM, such that the display module DM may exhibit high display quality.

Referring to FIGS. 6 and 8, the width W_{E} of the edge light blocking portion LSL-E on the plane parallel to the lower surface BSd of the base substrate BS may be greater than or equal to about 0.1 mm and less than about 2 mm. If the width W_{E} of the edge light blocking portion LSL-E is less than 0.1 mm, the edge control may not be easy when the second edge light blocking portion LSL-E2 and the inner light blocking portion LSL-I are formed. If the width W_{E} of the edge light blocking portion LSL-E is 2 mm or more, the edge light blocking portion LSL-E may be excessively large, and therefore the display quality of the display module DM may be deteriorated.

In an embodiment, the display module DM may include the edge fluorine film FF-E disposed on the outer portion of the lower surface of the base substrate BS and the light blocking layer LSL including the edge light blocking portion LSL-E and the inner light blocking portion LSL-I and may exhibit high light blocking characteristics. In such an embodiment, due to the structure of the edge fluorine film FF-E and the first edge light blocking portion LSL-E1, the edge control may be facilitated when the second edge light blocking portion LSL-E2 and the inner light blocking portion LSL-I are formed. Accordingly, the light blocking layer may be formed to be thick to a predetermined thickness or greater, and the occurrence of a slope at the edge of the light blocking layer LSL may be improved. Thus, an embodiment of the display module DM may exhibit characteristics of reduced light leakage and enhanced strength.

The display module DM described with reference to FIGS. 3 to 6 and the light blocking layer LSL described with reference to FIGS. 7 and 8 may be included in the electronic device.

Referring back to FIG. 2, an embodiment of the electronic device EA may include the display module DM that generates an image, and the display module DM may include the base substrate, the display layer, the edge fluorine film, and the light blocking layer described above and may have the characteristics of the display module DM described above.

The electronic device may include the display module described above and may exhibit improved durability, high display quality, and high reliability characteristics.

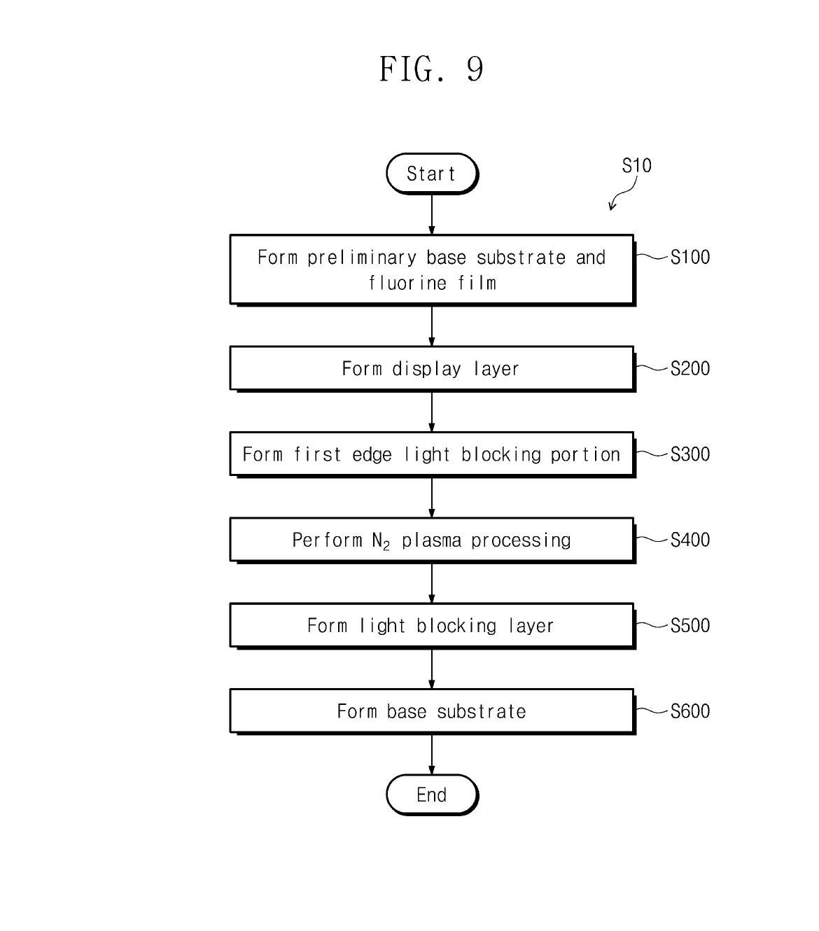

Hereinafter, an embodiment of a display module manufacturing method will be described with reference to FIGS. 9 to 13. In the description of an embodiment of the display module manufacturing method, repetitive detailed descriptions of the same or like elements as those of the display module DM described above with reference to FIGS. 3 to 6 and the light blocking layer LSL described with reference to FIGS. 7 and 8 will be omitted, and the following description will be focused on the difference.

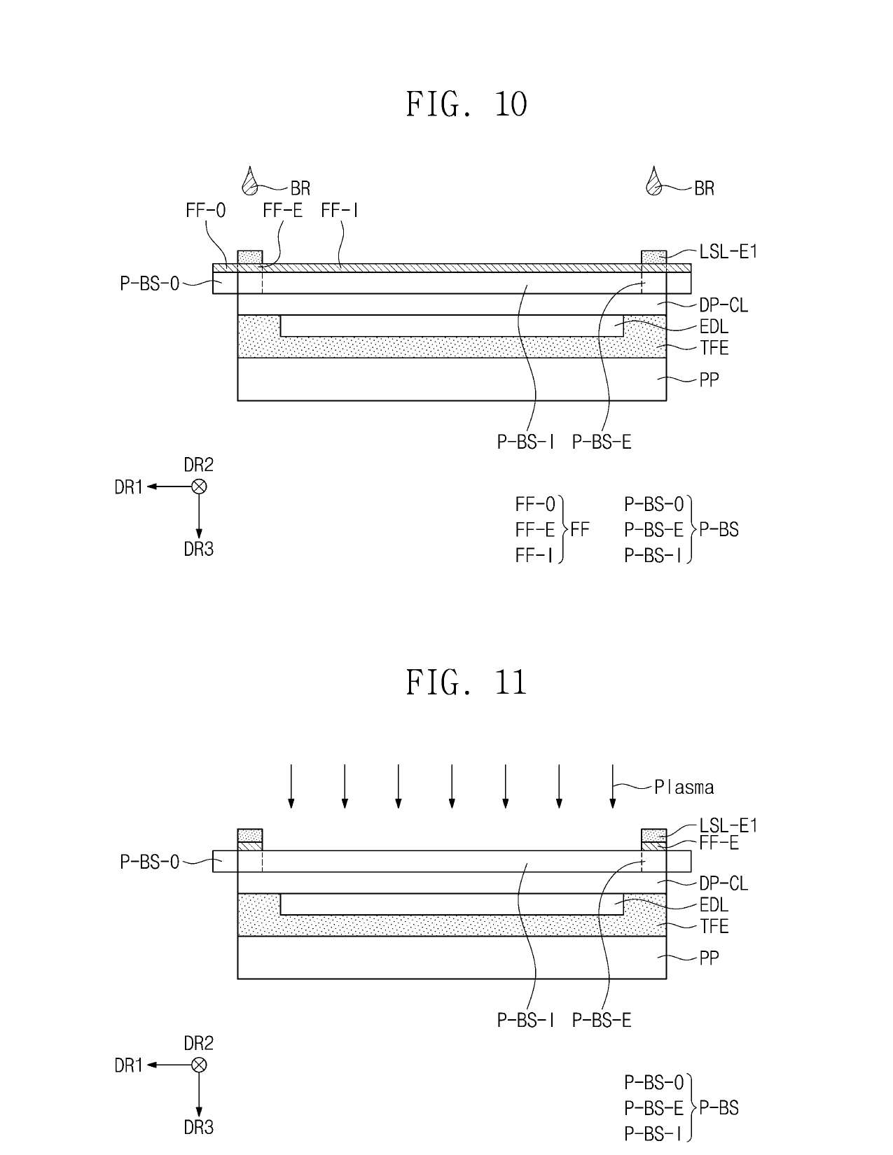

FIG. 9 is a flowchart illustrating the display module manufacturing method according to an embodiment. FIGS. 10 to 13 are sectional views illustrating processes of the display module manufacturing method according to an embodiment.

Referring to FIG. 9, an embodiment of the display module manufacturing method S10 includes process S100 of forming a preliminary base substrate and a fluorine film, process S200 of forming a display layer, process S300 of forming a first edge light blocking portion, process S400 of performing N₂ plasma processing, process S500 of forming a light blocking layer, and process S600 of forming a base substrate.

In process S100 of forming the preliminary base substrate and the fluorine film, the preliminary base substrate P-BS and the fluorine film FF on the lower surface of the preliminary base substrate P-BS are formed by etching the lower surface of the mother substrate with a fluorine solution.

The mother substrate may include glass. The thickness of the mother substrate may be adjusted to be thin by etching the mother substrate including glass with the fluorine solution. In this specification, the preliminary base substrate P-BS refers to a substrate obtained by etching the mother substrate. In process S600 of forming the base substrate, which will be described below, the base substrate BS may be formed by removing the portion of the preliminary base substrate P-BS that does not overlap the light blocking layer LSL. The thickness of the preliminary base substrate P-BS may be greater than or equal to about 0.1 mm and less than about 0.3 mm. In an embodiment, for example, the preliminary base substrate P-BS may have a thickness of about 0.2 mm. In the etching process, the fluorine solution, which is an etchant, may be applied only to the lower surface of the mother substrate. In the etching process, the upper surface of the mother substrate may be protected by a protective film, or the etchant may be provided only to the lower surface of the mother substrate. Accordingly, only the target surface, such as the lower surface of the mother substrate, may be etched.

In process S200 of forming the display layer, the display layer EDL including the light emitting elements is formed on the upper surface of the preliminary base substrate P-BS that faces the lower surface of the preliminary base substrate P-BS. A process of forming the circuit layer DP-CL may be further performed before process S200 of forming the display layer. A process of forming the encapsulation layer TFE and/or a process of forming the optical member PP may be further performed after process S200 of forming the display layer.

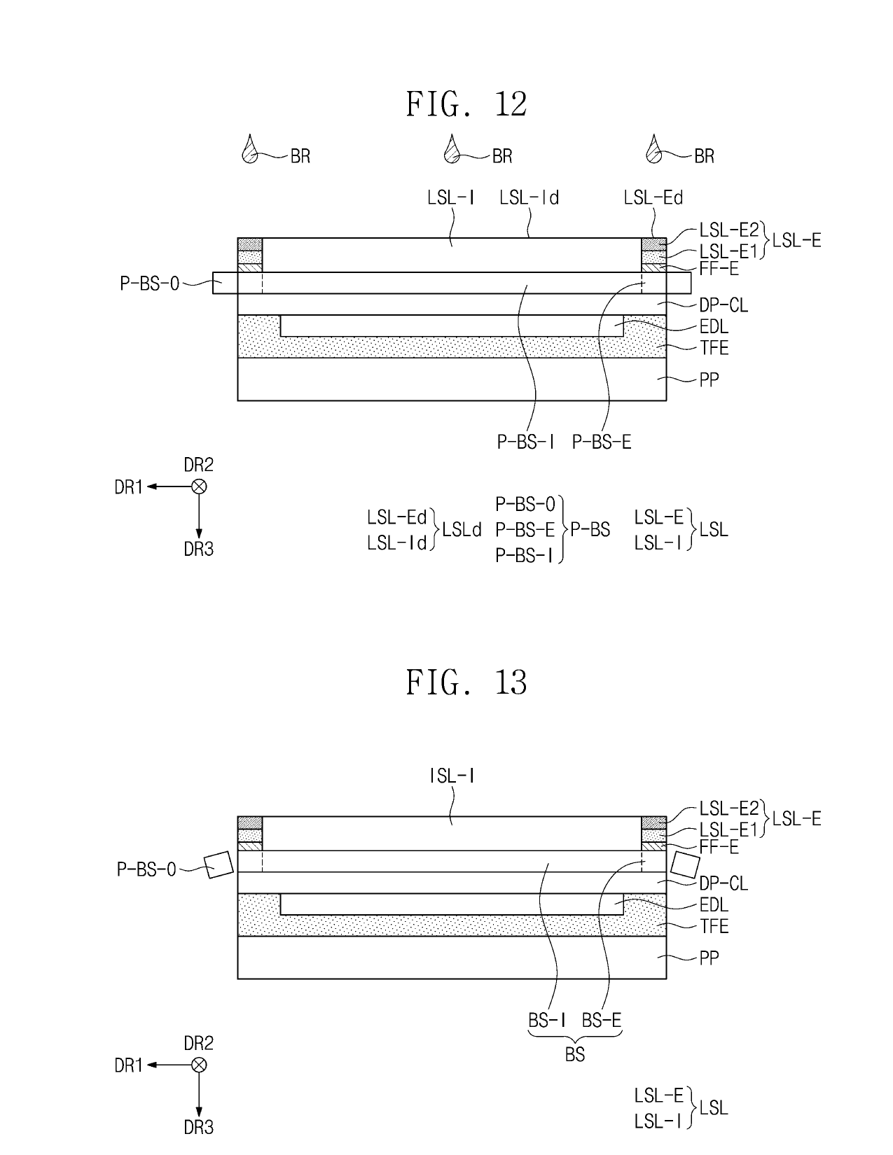

Referring to FIG. 10, the preliminary base substrate P-BS may be divided into an outer preliminary base substrate P-BS-O not overlapping the finally formed light blocking layer LSL (refer to FIG. 13), an edge preliminary base substrate P-BS-E overlapping the edge light blocking portion LSL-E (refer to FIG. 12), and an inner preliminary base substrate P-BS-I overlapping the inner light blocking portion LSL-I (refer to FIG. 12).

Depending on the position overlapping the preliminary base substrate P-BS, the fluorine film FF may be divided into an outer fluorine film FF-O overlapping the outer preliminary base substrate P-BS-O, an edge fluorine film FF-E overlapping the edge preliminary base substrate P-BS-E, and an inner fluorine film FF-I overlapping the inner preliminary base substrate P-BS-I.

FIG. 10 is a view illustrating process S300 of forming the first edge light blocking portion. Referring to FIG. 10, in process S300 of forming the first edge light blocking portion, the first edge light blocking portion LSL-E1 is formed on a portion of the lower surface of the fluorine film FF. The portion may be a portion that overlaps the edge preliminary base substrate P-BS-E and the edge fluorine film FF-E. The first edge light blocking portion LSL-E1 may be formed by providing a black resin BR on the portion of the fluorine film FF.

FIG. 11 is a view illustrating process S400 of performing the N₂ plasma processing. Referring to FIG. 11, in process S400 of performing the N₂ plasma processing, the fluorine film FF is processed with N₂ plasma from below (i.e., in a direction toward the lower surface of) the preliminary base substrate P-BS. Since a nitrogen radical generated in a plasma state is combined with fluorine to form a volatile compound such as NF₃, the fluorine film of the area exposed to the N₂ plasma may be removed. That is, when the fluorine film FF is processed with the N₂ plasma from below the preliminary base substrate P-BS, the outer fluorine film FF-O and the inner fluorine film FF-I except for the edge fluorine film FF-E masked by the first edge light blocking portion LSL-E1 may be removed.

For example, in an embodiment of the display module manufacturing method, process S400 of performing the N₂ plasma processing may be performed under the conditions of N₂ at 400 liter per minute (LPM), clean dry air (CDA) at 4 liter per minute (LPM), and plasma generation power of 1.36 kilowatts (kW). In process S400 of performing the N₂ plasma processing, the fluorine film of the area exposed to the N₂ plasma may be removed.

FIG. 12 is a view illustrating process S500 of forming the light blocking layer. Referring to FIG. 12, in process S500 of forming the light blocking layer, the light blocking layer LSL including the first edge light blocking portion LSL-E1, the second edge light blocking portion LSL-E2 overlapping the first edge light blocking portion LSL-E1, and the inner light blocking portion LSL-I not overlapping the first edge light blocking portion LSL-E1 is formed by providing the black resin BR to the lower surface of the first edge light blocking portion LSL-E1 and the lower surface of the preliminary base substrate P-BS that is exposed after the N₂ plasma processing. That is, the second edge light blocking portion LSL-E2 may overlap the first edge light blocking portion LSL-E1, the edge fluorine film FF-E, and the edge preliminary base substrate P-BS-E, and the inner light blocking portion LSL-I may overlap the inner preliminary base substrate P-BS-I. In the process of providing the black resin BR, the second edge light blocking portion LSL-E2 and the inner light blocking portion LSL-I may be integrally formed with each other as a single unitary indivisible part. In an embodiment where the second edge light blocking portion LSL-E2 and the inner light blocking portion LSL-I are integrally formed with each other as a single unitary indivisible part to form a single structure, the light blocking layer LSL may exhibit high durability characteristics.

Referring to FIG. 12, the lower surface LSL-Ed of the second edge light blocking portion LSL-E2 and the lower surface LSL-Id of the inner light blocking portion LSL-I exposed in process S500 of forming the light blocking layer may be formed to be on a same plane or coplanar. Since the structure of the edge fluorine film FF-E and the first edge light blocking portion LSL-E1 exist so that edge control of the black resin BR is facilitated when the second edge light blocking portion LSL-E2 and the inner light blocking portion LSL-I are formed, the lower surface LSL-Ed of the second edge light blocking portion LSL-E2 and the lower surface LSL-Id of the inner light blocking portion LSL-I that are exposed may be formed to be on a same plane or coplanar. That is, the lower surface LSLd of the light blocking layer may be formed to be a flat surface. In such an embodiment where the lower surface LSLd of the light blocking layer LSL is a flat surface, the light leakage phenomenon of the display module may be improved. Thus, the display module may exhibit high display quality, and an edge margin may be increased in the process of manufacturing the display module. The expression “the edge margin is increased” may mean that as the occurrence of a slope at the edge of the light blocking layer is improved, a discarded material of the edge portion of the light blocking layer is reduced in the manufacturing process of the display module and thus the display module is capable of being more efficiently manufactured.

FIG. 13 is a view illustrating process S600 of forming the base substrate. Referring to FIG. 13, in process S600 of forming the base substrate, the base substrate BS may be formed by removing the portion of the preliminary base substrate P-BS that does not overlap the light blocking layer LSL. The portion of the preliminary base substrate P-BS that does not overlap the light blocking layer LS and that is removed may be the outer preliminary base substrate P-BS-O. Accordingly, the preliminary base substrate portion of the portion that protrudes without overlapping other components of the display module may be removed from the finally manufactured display module.

In an embodiment, process S300 of forming the first edge light blocking portion and process S500 of forming the light blocking layer may each include a process of printing the black resin BR. Accordingly, the first edge light blocking portion LSL-E1, the second edge light blocking portion LSL-E2, and the inner light blocking portion LSL-I may each include a black coloring agent. In such an embodiment, since the process of printing the black resin is included, the light blocking layer may be easily formed in a desired area.

In an embodiment, process S300 of forming the first edge light blocking portion and process S500 of forming the light blocking layer may each include a process of curing the printed black resin after the process of printing the black resin. In the process of curing the printed black resin, ultraviolet (UV) light or heat may be used to cure the black resin.

In an embodiment, in process S500 of forming the light blocking layer, the inner light blocking portion LSL-I may be formed in a rectangular shape on the plane parallel to the lower surface of the preliminary base substrate P-BS. In an embodiment, the edge light blocking portion LSL-E may be formed to surround the inner light blocking portion LSL-I such that the light blocking layer LSL has a rectangular shape on the plane.

An embodiment of the display module manufacturing method S10 forms the first edge light blocking portion LSL-E1 under the fluorine film FF and then performs the N₂ plasma processing from below the preliminary base substrate P-BS. In the process of forming the second edge light blocking portion LSL-E2 and the inner light blocking portion LSL-I, the edge fluorine film FF-E and the first edge light blocking portion LSL-E1 may serve as a structure. Accordingly, edge control of the material (e.g., the black resin) of the second edge light blocking portion LSL-E2 and the inner light blocking portion LSL-I may be facilitated by the structure. Thus, the occurrence of a slope at the edge of the light blocking layer LSL may be improved, and an edge margin may be increased in the manufacturing process.

In an embodiment, as described above, the display module may include the edge fluorine film disposed on the outer portion of the lower surface of the base substrate and the light blocking layer including the edge light blocking portion and the inner light blocking portion. Accordingly, light leakage of the display module may be reduced, and the strength may be enhanced.

An embodiment of the display module manufacturing method may include the process of forming the first edge light blocking portion, the process of performing the N₂ plasma processing, and the process of forming the light blocking layer. Accordingly, the edge control of the light blocking layer may be facilitated. Thus, the occurrence of a slope at the edge of the light blocking layer may be improved.

An embodiment of the electronic device may include the display module described above and may exhibit improved durability and high display quality.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display module comprising:
a base substrate;
a display layer disposed on the base substrate, wherein the display layer includes a light emitting element;
an edge fluorine film disposed on an outer portion of a lower surface of the base substrate which faces an upper surface of the base substrate; and
a light blocking layer including an edge light blocking portion, which overlaps the edge fluorine film, and an inner light blocking portion disposed on the lower surface of the base substrate not to overlap the edge fluorine film.

2. The display module of claim 1, wherein the edge light blocking portion includes:
a first edge light blocking portion directly disposed on a lower surface of the edge fluorine film; and
a second edge light blocking portion directly disposed on a lower surface of the first edge light blocking portion.

3. The display module of claim 2, wherein the second edge light blocking portion and the inner light blocking portion are integrally formed with each other as a single unitary indivisible part.

4. The display module of claim 1, wherein a lower surface of the light blocking layer is a flat surface.

5. The display module of claim 1, wherein the edge light blocking portion has a smaller thickness than the inner light blocking portion.

6. The display module of claim 1, wherein the base substrate includes glass.

7. The display module of claim 1, wherein the light blocking layer includes a black coloring agent.

8. The display module of claim 1, wherein the inner light blocking portion has a rectangular shape in a plan view, and
wherein the edge light blocking portion is disposed to surround the inner light blocking portion such that the light blocking layer has a rectangular shape in the plan view.

9. The display module of claim 1, wherein the edge light blocking portion has a width greater than or equal to about 0.1 mm and less than about 2 mm on in a plan view.

10. A method for manufacturing a display module, the method comprising:
forming a preliminary base substrate and a fluorine film on a lower surface of the preliminary base substrate by etching a lower surface of a mother substrate with a fluorine solution;
forming a display layer including a light emitting element on an upper surface of the preliminary base substrate which faces the lower surface of the preliminary base substrate;
forming a first edge light blocking portion on a portion of a lower surface of the fluorine film;
processing the fluorine film with N₂ plasma from below the preliminary base substrate;
forming a light blocking layer including the first edge light blocking portion, a second edge light blocking portion overlapping the first edge light blocking portion, and an inner light blocking portion not overlapping the first edge light blocking portion, by providing a black resin to a lower surface of the first edge light blocking portion and the lower surface of the preliminary base substrate which is exposed after the processing the fluorine film with N₂ plasma; and
forming a base substrate by removing a portion of the preliminary base substrate not overlapping the light blocking layer.

11. The method of claim 10, wherein in the forming the light blocking layer, an exposed lower surface of the second edge light blocking portion and an exposed lower surface of the inner light blocking portion are formed to be on a same plane.

12. The method of claim 10, wherein the mother substrate includes glass.

13. The method of claim 10, wherein each of the forming the first edge light blocking portion and the forming the light blocking layer includes printing the black resin.

14. The method of claim 10, wherein in the forming the light blocking layer, the inner light blocking portion has a rectangular shape in a plan view, and the first edge light blocking portion and the second edge light blocking portion are respectively formed to surround the inner light blocking portion such that the light blocking layer has a rectangular shape in the plan view.

15. The method of claim 10, wherein in the forming the first edge light blocking portion, the first edge light blocking portion has a width greater than or equal to about 0.1 mm and less than about 2 mm in a plan view.

16. An electronic device comprising:
a display module which generates an image,
wherein the display module includes:
a base substrate;
a display layer disposed on the base substrate, wherein the display layer includes a light emitting element;
an edge fluorine film disposed on an outer portion of a lower surface of the base substrate which faces an upper surface of the base substrate; and
a light blocking layer including an edge light blocking portion, which overlaps the edge fluorine film, and an inner light blocking portion disposed on the lower surface of the base substrate not to overlap the edge fluorine film.

17. The electronic device of claim 16, wherein the edge light blocking portion includes:
a first edge light blocking portion directly disposed on a lower surface of the edge fluorine film; and
a second edge light blocking portion directly disposed on a lower surface of the first edge light blocking portion.

18. The electronic device of claim 17, wherein the second edge light blocking portion and the inner light blocking portion are integrally formed with each other as a single unitary indivisible part.

19. The electronic device of claim 16, further comprising:
at least one selected from a processor, a memory, and a power module.

20. The electronic device of claim 16, wherein the electronic device is a television, a monitor, a billboard, a personal computer, a laptop computer, a personal digital assistant, a device for a vehicle, a game machine, a smart phone, a tablet computer, a smart watch, or a camera.
